(19) United States
(12) Patent Application Publication
(10) Pub. No.: US 2011/0062469 A1
(43) Pub. Date: Mar. 17, 2011

(54) MOLDED LENS INCORPORATING A WINDOW ELEMENT

(75) Inventors: Michael D. CAMRAS, Sunnyvale, CA (US); Nanze Patrick WANG, San Jose, CA (US); Hendrik J.B. JAGT, Eindhoven (NL); Helena TICHA, Czech Republic (CZ); Ladislav TICHY, Czech Republic (CZ)

(73) Assignees: KONINKLIJKE PHILIPS ELECTRONICS N.V., EINDHOVEN (NL); PHILIPS LUMILEDS LIGHTING COMPANY, LLC, San Jose, CA (US)

(21) Appl. No.: 12/561,342

(22) Filed: Sep. 17, 2009

(51) Int. Cl. H01L 33/00

(52) U.S. Cl. 257/98; 438/27; 977/773; 257/E33.059; 257/E33.067

(57) ABSTRACT

A light emitter includes a light-emitting device (LED) die and an optical element over the LED die. The optical element includes a lens, a window element, and a bond at an interface disposed between the lens and the window element. The window element may be a wavelength converting element or an optically flat plate. The window element may be directly bonded or fused to the lens, or the window element may be bonded by one or more intermediate bonding layers to the lens. The bond between the window element and the lens may have a refractive index similar to that of the window element, the lens, or both.

### STATEMENT OF GOVERNMENT SPONSORED RESEARCH

One or more embodiments of this invention were made with Government support under contract no. DE-FC26-08NT01583 awarded by Department of Energy. The Government has certain rights in this invention.

### FIELD OF INVENTION

The present disclosure relates to light emitters with light-emitting devices (LEDs).

### DESCRIPTION OF RELATED ART

FIG. 1 illustrates a cross-sectional view of a light emitter 100. Light emitter 100 includes a light-emitting device (LED) die 102 and a phosphor layer 104 on the LED die. LED die 102 is mounted on a support 106. Support 106 may include conductive traces and leads that couple LED die 102 to external components. Support 106 may also include a heat sink to dissipate heat from light emitter 100.

A lens 108 is mounted to support 106 over LED die 102 and phosphor layer 104, and an encapsulant 110 inside the lens seals the LED die and the phosphor layer. Exposed to light, heat, and/or humidity, lens 108 and/or encapsulant 110 may turn yellow or brown under high power short wavelength blue or ultraviolet (UV) LED operation.

### SUMMARY

In one or more embodiments of the present disclosure, a light emitter includes a light-emitting device (LED) die and an optical element over or proximate to the LED die. The optical element may include a lens, a window element, and a bond at an interface disposed between the lens and the window element. The window element may be a wavelength converting element or an optically flat plate. The window element may be directly bonded or fused to the lens, or the window element may be bonded by one or more intermediate bonding layers to the lens. The bond between the window element and the lens may have a refractive index similar to that of the window element, the lens, or both.

### BRIEF DESCRIPTION OF THE DRAWINGS

In the drawings:

FIG. 1 illustrates a cross-sectional view of a prior art light emitter;

FIGS. 2A, 2B, 3A, 3B, 4A, and 4B illustrate cross-sectional views of a light emitter in embodiments of the present disclosure;

FIG. 5 illustrates an apparatus that can be used in a process for forming a bond between a lens and a window element in one or more embodiments of the present disclosure;

FIGS. 6 to 13 illustrate cross-sectional views of various types of lenses with window elements in embodiments of the present disclosure;

FIGS. 14 and 15 illustrate cross-sectional views of light emitters in embodiments of the present disclosure;

FIG. 16 illustrates an apparatus that can be used in a process for forming bonding layers on a window element in one or more embodiments of the present disclosure;

FIG. 17 illustrates a window element with bonding layers that can be formed in the apparatus of FIG. 16 in one or more embodiments of the present disclosure;

FIG. 18 illustrates an apparatus that can be used in a process for forming a bonding layer on a lens in one or more embodiments of the present disclosure;

FIG. 19 illustrates a lens with a bonding layer that can be formed in the apparatus of FIG. 18 in one or more embodiments of the present disclosure; and

FIG. 20 is a cross-sectional view of a lens including grooves in the shape of a Fresnel lens in one or more embodiments of the present disclosure.

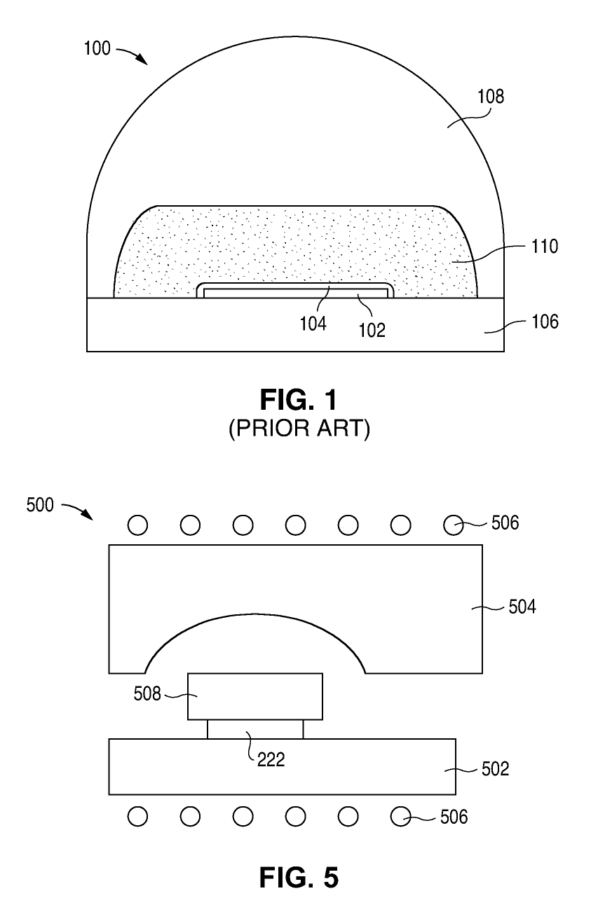

Use of the same reference numbers in different figures indicates similar or identical elements.

### DETAILED DESCRIPTION

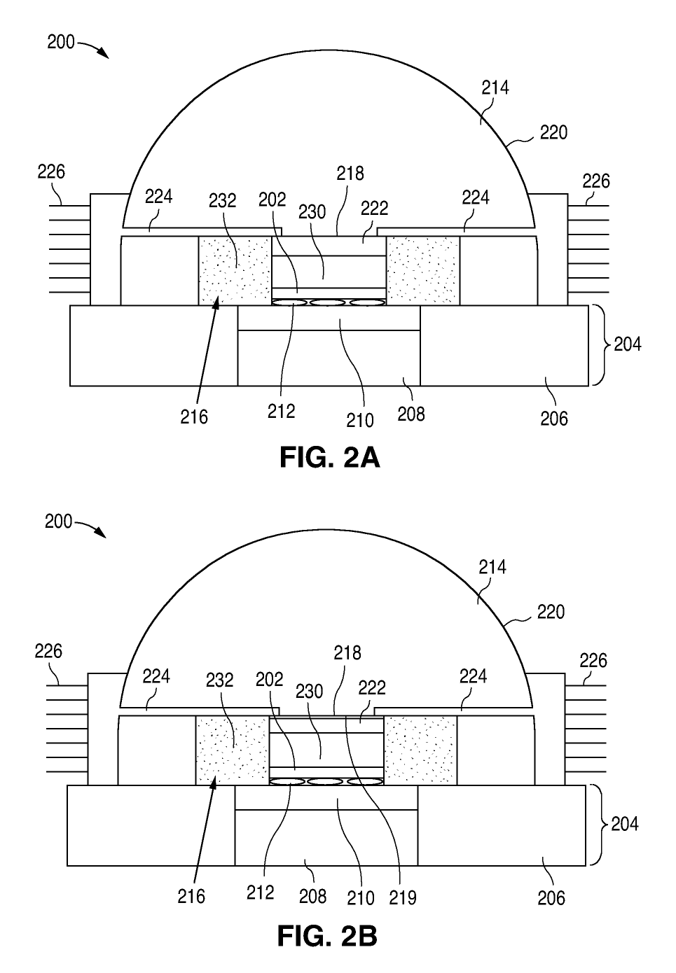

FIG. 2A illustrates a cross-sectional view of a light emitter 200 in accordance with one or more embodiments of the present disclosure. Light emitter 200 includes an LED die 202 mounted on a support 204.

LED die 202 includes an n-type layer, a light-emitting layer (commonly referred to as the “active region”) proximate the n-type layer, a p-type layer proximate the light-emitting layer, and a conductive reflective layer proximate the p-type layer. In one or more embodiments, a conductive transparent contact layer may be used, such as indium tin oxide, aluminum doped zinc oxide, and zinc doped indium oxide for example. Depending on the embodiment, n- and p-type metal contacts to the n and the p-type layers may be disposed on the same side of LED die 202 in a “flip chip” arrangement. The semiconductor layers are epitaxially grown on a substrate or superstrate, which may be removed so that only the epitaxial layers remain.

Support 204 may include a housing 206 with electrical leads, a heat sink 208 in the housing, and a submount 210 mounted on the heat sink. LED die 202 is mounted on submount 210 via contact elements 212, such as solder, gold, or gold-tin interconnects. Submount 210 may include a substrate with through-vias or may include on-submount redistribution of the metal pattern of LED die 202. Bond wires may couple bond wire pads on submount 210 to the electrical leads of housing 206, which pass electrical signals between light emitter 200 and external components.

An underfill may be applied between LED die 202 and submount 210. The underfill may provide mechanical support and may seal voids between LED die 202 and submount 210 from contaminants. The underfill may block any edge emission from the side of LED die 202. The underfill material may have good thermal conductivity and may have a coefficient of thermal expansion (CTE) that approximately matches at least one of the LED die 202, submount 210, and contact elements 212. Additionally, the underfill material may have a CTE that approximately matches at least one of a lens 214, a window element 222, a first silicone 230, and a second silicone 232 as described later, or at least one of a lens 314, a bonding layer 330, and a protective side coating 332 as described later. CTEs may be matched to within 500% or less in one or more embodiments, to within 100% or less in one or more embodiments, to within 50% or less in one or more embodiments, and to within 30% or less of each other in one or more embodiments. The underfill material may be epoxy or silicone, and may have a fill material.

More information can be found in U.S. Pat. Nos. 7,462,502, 7,419,839, 7,279,345, 7,064,355, 7,053,419, and 6,946,309, and U.S. Patent App. Pub. No. 20050247944, which are commonly assigned and incorporated by reference in their entirety.

An optical element is located over or proximate to LED die 202. In one or more embodiments of the present disclosure, the optical element includes a high index lens 214 that extracts light from LED die 202. Lens 214 includes a cavity 216 with a ceiling 218. Lens 214 has a refractive index (RI) greater than a conventional silicone lens. Lens 214 may have a RI of 1.5 or greater (e.g., 1.7 or greater) at the wavelengths emitted by LED die 202. Lens 214 may have a shape and a size such that light entering the lens from LED die 202 will intersect a lens exit surface 220 at near normal incidence, thereby increasing light output by reducing total internal reflection at the interface between the lens exit surface and the ambient medium (e.g., air).

Lens 214 may be a hemispheric lens or a Fresnel lens. Lens 214 may also be an optical concentrator, which includes total internal reflectors and optical elements having a wall coated with a reflective metal, a dielectric material, or a reflective coating to reflect or redirect incident light. An example of a reflective coating is the Munsell White Reflectance Coating from Munsell Color Services of New York.

Lens 214 may be formed from any combination of optical glass, high index glass, sapphire, diamond, silicon carbide, alumina, III-V semiconductors such as gallium phosphide, II-VI semiconductors such as zinc sulfide, zinc selenide, and zinc telluride, group IV semiconductors and compounds, metal oxides, metal fluorides, an oxide of any of the following: aluminum, antimony, arsenic, bismuth, calcium, copper, gallium, germanium, lanthanum, lead, niobium, phosphorus, tellurium, thallium, titanium, tungsten, zinc, or zirconium, polycrystalline aluminum oxide (transparent alumina), aluminum oxynitride (AlON), cubic zirconia (CZ), gadolinium gallium garnet (GGG), gallium phosphide (GaP), lead lanthanum zirconate titanate (PLZT), lead zirconate titanate (PZT), silicon aluminum oxynitride (SiAlON), silicone carbide (SiC), silicon oxynitride (SiON), strontium titanate, yttrium aluminum garnet (YAG), zinc sulfide (ZnS), spinel, Schott glass LaFN21, LaSFN35, LaF2, LaF3, LaF10, NZK7, NLAF21, LaSFN18, SF59, or LaSF3, Ohara glass SLAM60 or SLAH51, or any combination thereof. Schott glasses are available from Schott Glass Technologies Incorporated, of Duryea, Pa., and Ohara glasses are available from Ohara Corporation in Somerville, N.J.

Lens 214 may include luminescent material that converts light of wavelengths emitted by LED die 202 to other wavelengths. In one or more embodiments, a coating on lens exit surface 220 of lens 214 includes the luminescent material. The luminescent material may include conventional phosphor particles, organic semiconductors, II-VI or III-V semiconductors, II-VI or III-V semiconductor quantum dots or nano-crystals, dyes, polymers, or materials such as gallium nitride (GaN) that luminesce. Alternatively, a region of lens 214 near lens exit surface 220 may be doped with a luminescent material. Alternatively, lens 214 may contain a wavelength converting region. Lens 214 may include an anti-reflection coating (AR), either single or multi-layer, on lens exit surface 220 to further suppress reflection at the exit surface.

Lens 214 may also comprise any of the materials listed later for window element 222, bonding layer 219, bonding layer 330, bonding layer 1402, and bonding layer 1410.

More information can be found in U.S. Pat. Nos. 7,279,345, 7,064,355, 7,053,419, 7,009,213, 7,462,502, and 7,419,839, which are commonly assigned and incorporated by reference in their entirety.

In one or more embodiments of the present disclosure, the optical element includes a window element 222 that modifies the emission spectrum of LED die 202, provides a flat optical surface, or both. Window element 222 may be directly bonded or fused to ceiling 218 of lens 214 to form an integral element. Window element 222 may be directly bonded or fused to ceiling 218 of lens 214, for example, during a molding process. Window element 222 may be placed on ceiling 218 before or while lens 214 becomes solid or hard, for example, by cooling or curing for example in a mold. Window element 222 may also be embedded into lens 214 at ceiling 218 by molding the lens under or over the window element for example in a mold.

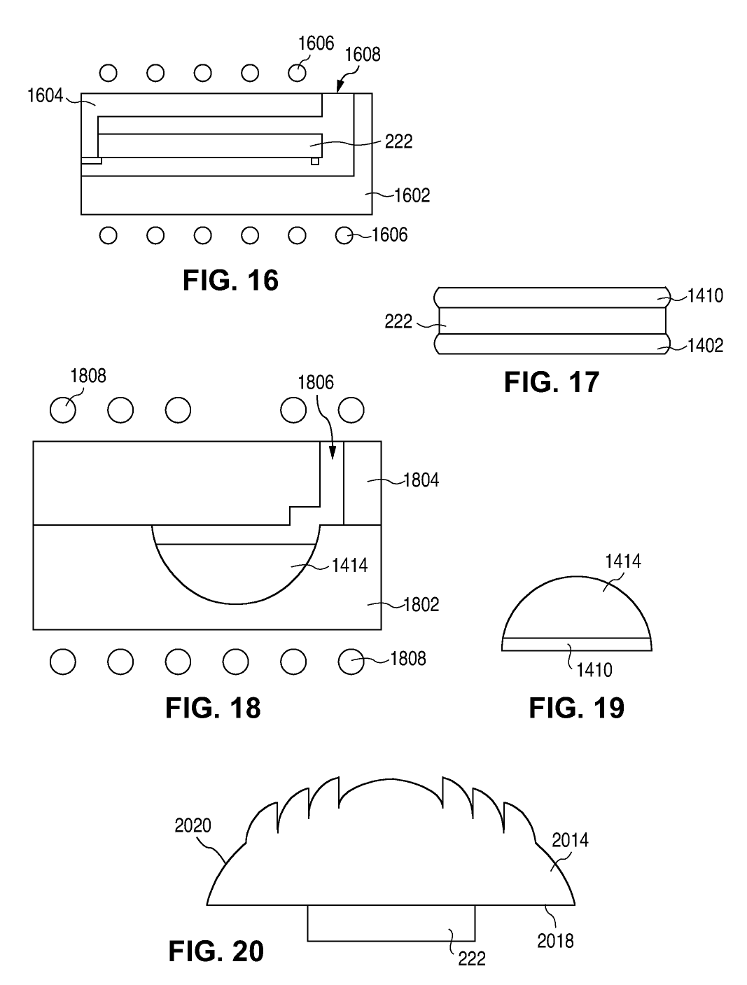

Alternatively, FIG. 2B shows that window element 222 may be bonded to lens 214 with a bonding layer 219 in processes for example described later in reference to FIGS. 16 to 19. Bonding layer 219 may comprise any of the materials listed later for a bonding layer 330, such as lead chloride, lead bromide, potassium fluoride, zinc fluoride, an oxide of aluminum, antimony, arsenic, bismuth, boron, lead, lithium, phosphorus, potassium, silicon, sodium, tellurium, thallium, tungsten, or zinc, or any mixtures thereof.

Window element 222 may have a RI of 1.5 or greater (e.g., 1.7 or greater) at the wavelengths emitted by LED die 202. The bond at the interface disposed between window element 222 and lens 214 may have a RI that substantially matches the RI of either or both of the window element and the lens, a RI that is intermediate to the RIs of the window element and the lens, or a RI that is greater than the RI of the window element or the lens. The RIs substantially match when they are within 100% or less in one or more embodiments, within 50% or less in one or more embodiments, within 25% or less in one or more embodiments, and within 10% or less of each other in one or more embodiments. For example, the RI of the bond and the RI of window element 222 or lens 214 may be within ±0.05 of each other. In one or more embodiments of the present disclosure, lens 214 with window element 222 is mounted on support 204 to enclose LED die 202.

Window element 222 may be formed from any of the materials and material combinations described for lens 214 and bonding layers 219, 330, 1402, and 1410, such as aluminum oxynitride (AlON), polycrystalline alumina oxide (transparent alumina), aluminum nitride, cubic zirconia, diamond, gallium nitride, gallium phosphide, sapphire, silicon carbide, silicon aluminum oxynitride (SiAlON), silicon oxynitride (SiON), spinel, zinc sulfide, or an oxide of tellurium, lead, tungsten, or zinc.

Window element 222 may have a CTE approximately matching that of lens 214 to reduce stress in the window element and to prevent the window element from becoming detached from the lens upon heating and cooling. CTE may be matched to within 100% or less in one or more embodiments, to within 50% or less in one or more embodiments, and to within 30% or less of each other in one or more embodiments.

In one or more embodiments of the present disclosure, window element 222 is a wavelength converting element that modifies the emission spectrum of LED die 202 to provide one or more desired colors of light. The thickness of the wavelength converting element may be controlled in response to the wavelength of the light produced by the LED die 202, which results in a highly reproducible correlated color temperature.

The wavelength converting element may be a ceramic phosphor plate for generating one color of light or a stack of ceramic phosphor plates for generating different colors of light. A ceramic phosphor plate, also referred to as “luminescent ceramics,” may be a ceramic slab of phosphor. The ceramic phosphor plate may have a RI of 1.4 or greater (e.g., 1.7 or greater) at the wavelengths emitted by LED die 202. The ceramic phosphor plate may be a Y₃Al₅O₁₂:Ce³⁺.

The ceramic phosphor plate may be an amber to red emitting rare earth metal-activated oxonitridoalumosilicate of the general formula (Ca_{1-x-y-z}SrₓBa_{y}Mg_{z})₁₋ₙ(Al_{1-a+b}Bₐ)Si_{1-b}N_{3-b}O_{b}:REₙ, wherein 0≦x≦1, 0≦y≦1, 0≦z≦1, 0≦a≦1, 0≦b≦1 and 0.002≦n≦0.2, and RE is selected from europium(II) and cerium(III). The phosphor in the ceramic phosphor plate may also be an oxido-nitrido-silicate of general formula EA_{2-z}Si₅₋ₐBₐN₈₋ₐOₐ:Ln_{z}, wherein 0<z≦1 and 0<a<5, including at least one element EA selected from the group consisting of Mg, Ca, Sr, Ba and Zn and at least one element B selected from the group consisting of Al, Ga and In, and being activated by a lanthanide selected from the group consisting of cerium, europium, terbium, praseodymium and mixtures thereof.

The ceramic phosphor plate may also be an aluminum garnet phosphors with the general formula (Lu_{1-x-y-a-b}YₓGd_{y})₃(Al_{1-z}Ga_{z})₅O₁₂: CeₐPr_{b}, wherein 0<x<1, 0<y<1, 0<z≦0.1, 0<a≦0.2 and 0<b≦0.1, such as Lu₃Al₅O₁₂:Ce³⁺ and Y₃Al₅O₁₂:Ce³⁺, which emits light in the yellow-green range; and (Sr_{1-x-y}BaₓCa_{y})_{2-z}Si₅₋ₐAlₐN₈₋ₐOₐ:Eu_{z}²⁺, wherein 0≦a<5, 0<x≦1, 0≦y≦1, and 0<z≦1 such as Sr₂Si₅N₈:Eu²⁺, which emits light in the red range. Other green, yellow, and red emitting phosphors may also be suitable, including (Sr_{1-a-b}Ca_{b}Ba_{c})SiₓN_{y}O_{z}:Euₐ²⁺ (a=0.002-0.2, b=0.0-0.25, c=0.0-0.25, x=1.5-2.5, y=1.5-2.5, 2=1.5-2.5) including, for example, SrSi₂N₂O₂:Eu²⁺; (Sr₁₋ᵤ₋ᵥ₋ₓMgᵤCaᵥBaₓ)(Ga_{2-y-z}Al_{y}In_{z}S₄):Eu²⁺ including, for example, SrGa₂S₄:Eu²⁺; Sr₁₋ₓBaₓSiO₄:Eu²⁺; and (Ca₁₋ₓSrₓ)S:Eu²⁺ wherein 0<x≦1 including, for example, CaS:Eu²⁺ and SrS:Eu²⁺. Other suitable phosphors include, for example, CaAlSiN₃:Eu²⁺, (Sr, Ca)AlSiN₃:Eu²⁺, and (Sr, Ca, Mg, Ba, Zn)(Al, B, In, Ga)(Si, Ge) N₃:Eu²⁺.

The ceramic phosphor plate may also have a general formula (Sr_{1-a-b}Ca_{b}Ba_{c}Mg_{d}Znₑ)SiₓN_{y}O_{z}:Euₐ²⁺, wherein 0.002≦a≦0.2, 0.0≦b≦0.25, 0.0≦c≦0.25, 0. 0≦d≦0.25, 0.0≦e≦0.25, 1.5≦x≦2.5, 1.5≦y≦2.5 and 1.5≦z≦2.5. The ceramic phosphor plate may also have a general formula of MmAaBbOoNn:Zz where an element M is one or more bivalent elements, an element A is one or more trivalent elements, an element B is one or more tetravalent elements, O is oxygen that is optional and may not be in the phosphor plate, N is nitrogen, an element Z that is an activator, n=2/3m+a+4/3b-2/3o, wherein m, a, b can all be 1 and o can be 0 and n can be 3. M is one or more elements selected from Mg (magnesium), Ca (calcium), Sr (strontium), Ba (barium) and Zn (zinc), the element A is one or more elements selected from B (boron), Al (aluminum), In (indium) and Ga (gallium), the element B is Si (silicon) and/or Ge (germanium), and the element Z is one or more elements selected from rare earth or transition metals. The element Z is at least one or more elements selected from Eu (europium), Mn (manganese), Sm (samarium) and Ce (cerium). The element A can be Al (aluminum), the element B can be Si (silicon), and the element Z can be Eu (europium).

The ceramic phosphor plate may also be an Eu²⁺ activated Sr—SiON having the formula (Sr_{1-a-b}Ca_{b}Ba_{c})SiₓN_{y}Oₓ:Euₐ, wherein a=0.002-0.2, b=0.0-0.25, c=0.0-0.25, x=1.5-2.5, y=1.5-2.5, y=1.5-2.5.

The ceramic phosphor plate may also be a chemically-altered Ce:YAG phosphor that is produced by doping the Ce:YAG phosphor with the trivalent ion of praseodymium (Pr). The ceramic phosphor plate may include a main fluorescent material and a supplemental fluorescent material. The main fluorescent material may be a Ce:YAG phosphor and the supplementary fluorescent material may be europium (Eu) activated strontium sulfide (SrS) phosphor (“Eu:SrS”). The main fluorescence material may also be a Ce:YAG phosphor or any other suitable yellow-emitting phosphor, and the supplementary fluorescent material may also be a mixed ternary crystalline material of calcium sulfide (CaS) and strontium sulfide (SrS) activated with europium ((CaₓSr₁₋ₓ)S:Eu²⁺). The main fluorescent material may also be a Ce:YAG phosphor or any other suitable yellow-emitting phosphor, and the supplementary fluorescent material may also be a nitrido-silicate doped with europium. The nitrido-silicate supplementary fluorescent material may have the chemical formula (Sr_{1-x-y-z}BaₓCa_{y})₂Si₅N₈:Eu_{z}²⁺ where 0≦x, y≦0.5 and 0≦z≦0.1.

The ceramic phosphor plate may also have a blend of any of the above described phosphors.

More information can be found in U.S. Pat. Nos. 7,462,502, 7,419,839, 7,544,309, 7,361,938, 7,061,024, 7,038,370, 6,717,353, and 6,680,569, and U.S. Pat. App. Pub. No. 20060255710, which are commonly assigned and incorporated by reference in their entirety.

In one or more embodiments of the present disclosure, window element 222 is an optically flat plate with an optically flat surface that faces LED die 202. The optically flat plate may be sapphire, glass, diamond, silicon carbide (SiC), aluminum nitride (AlN), or any transparent, translucent, or scattering ceramic. In one or more embodiments, window element 222 may be any of the materials listed above for lens 214 and bonding layers 219, 330, 1402, and 1410. The optically flat plate may have a RI of 1.5 or greater (e.g., 1.7 or greater) at the wavelengths emitted by LED die 202.

In one or more embodiments of the present disclosure, the optical element may include an optional heat sink 224 for extracting heat from light emitter 200. Heat sink 224 may have optional fins 226 (only two are labeled). Heat sink 224 may be incorporated by molding, for example, in or on lens 214. Heat sink 224 may be layers, plates, slabs, or rings. If heat sink 224 is transparent, translucent, or scattering, it may be in the optical path. For example, it may be located directly on window element 222. Heat sink 224 may be diamond, silicon carbide (SiC), single crystal aluminum nitride (AlN), gallium nitride (GaN), or aluminum gallium nitride (AlGaN), and it may be part of lens 214, window element 222, or any part of the optical element. If heat sink 224 is opaque, it may not be in the optical path. For example, it may contact the edge of window element 222. Heat sink 224 may be silicon, aluminum nitride (polycrystalline, sintered, hot pressed), metals such as silver, aluminum, gold, nickel, vanadium, copper, tungsten, metal oxides, metal nitrides, metal fluorides, thermal greases or any combinations thereof. Heat sink 224 can be reflective to the light being generated and may act as a side coating.

In one or more embodiments of the present disclosure, a first silicone 230 is applied on one or both of the LED die 202 and window element 222 so the first silicone is disposed between them after lens 214 is mounted on support 204. First silicone 230 helps to extract light from LED die 202 to window element 222. First silicone 230 may also act as a mechanical buffer to insulate LED die 202 from any external impact to lens 214, and may make light emitter 200 more robust. First silicone 230 may be a polydimethylsiloxane (PDMS) silicone with a RI of 1.4 or greater at the wavelengths emitted by LED die 202.

A second silicone 232 is introduced into the remaining space in cavity 216 after lens 214 is mounted on support 204. Second silicone 232 may be filled with reflective or scattering particles. Second silicone 232 may cover the edge of window element 222 to reduce edge emission, which may be important when the window element is a wavelength converting element. Second silicone 232 may also cover the edge of first silicone 230 and LED die 202 to reduce edge emission and to help to channel light from the LED die to window element 222. Second silicone 232 may also serve as an underfill between LED 202 and support 204 instead of a separate underfill. Second silicone 232 may be a phenyl substituted silicone with a RI of 1.5 or greater at the wavelengths emitted by LED die 202, and may be filled with reflective particles such as one or more of aluminum nitride, aluminum oxynitride (AlON), barium sulfate, barium titanate, calcium titanate, cubic zirconia, diamond, gadolinium gallium garnet (GGG), lead lanthanum zirconate titanate (PLZT), lead zirconate titanate (PZT), sapphire, silicon aluminum oxynitride (SiAlON), silicon carbide, silicon oxynitride (SiON), strontium titanate, titanium oxide, yttrium aluminum garnet (YAG), zinc selenide, zinc sulfide, and zinc telluride, for example. The interfacial boundary between silicones 230 and 232 may serve as a barrier to prevent contaminants from crossing into the first silicone and accumulating in the optical path or on window element 222.

In one or more alternative embodiments, light emitter 200 does not include second silicone 232. Instead, the entire cavity 216 is filled with first silicone 230.

In one or more alternative embodiments, light emitter 200 does not include first silicone 230 and second silicone 232. Instead, an air gap is formed between LED die 202 and window element 222. Without first silicone 230, an oversize window element 222 may be used to capture as much emission from LED die 202 as possible. The oversize window element 222 may span across cavity ceiling 218 and may even cover the cavity sidewalls.

In one or more embodiments of the present disclosure, the optical element is a lens 214 bonded to LED die 202. Bonding layer 219 may be used to bond lens 214 to LED die 202. This is further described in the incorporated references before and after.

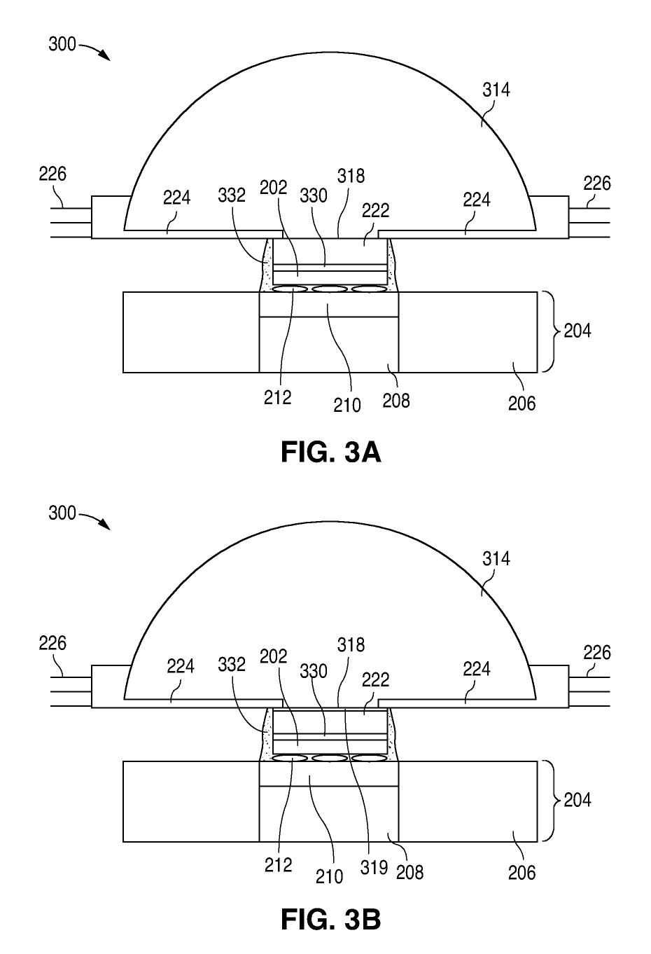

FIG. 3A illustrates a cross-sectional view of a light emitter 300 in one or more embodiments of the present disclosure. Light emitter 300 includes LED die 202 mounted on support 204. An optical element is located over or proximate to LED die 202. In one or more embodiments of the present disclosure, the optical element includes a high index lens 314 that extracts light from LED die 202. Lens 314 may have a dome-like shape with a bottom surface 318. Lens 314 may have a RI of 1.5 or greater (e.g., 1.7 or greater). Lens 314 may be made from any material described above for lens 214. As similarly described above for lens 214, lens 314 may include a luminescent material that converts light of wavelengths emitted by LED die 202 to other wavelengths.

In one or more embodiments of the present disclosure, the optical element includes a window element 222 that is directly bonded or fused to bottom surface 318 of lens 314 to form an integral element. Window element 222 may be directly bonded or fused to bottom surface 318 of lens 314, for example, during a molding process. Window element 222 may be placed on bottom surface 318 before or while lens 314 becomes solid or hard by cooling or curing for example in a mold. Window element 222 may also be embedded into lens 314 at bottom surface 318 by molding the lens under or over the window element for example in a mold.

Alternatively, FIG. 3B shows that window element 222 may be bonded to lens 314 with a bonding layer 319 in processes for example described later in reference to FIGS. 16 to 19. Bonding layer 319 may also be any of the materials listed later for a bonding layer 330, such as lead chloride, lead bromide, potassium fluoride, zinc fluoride, an oxide of aluminum, antimony, bismuth, boron, lead, lithium, phosphorus, potassium, silicon, sodium, tellurium, thallium, tungsten, or zinc, or any mixtures thereof.

As previously discussed, window element 222 may have a RI of 1.5 or greater (e.g., 1.7 or greater) at the wavelengths emitted by LED die 202. The bond at the interface disposed between window element 222 and lens 314 has a RI that substantially matches the RI of either or both of the window element and the lens, a RI that is intermediate to the RIs of the window element and the lens, or a RI that is greater than the window element or the lens. The RIs substantially match when they are within 100% or less in one or more embodiments, within 50% or less in one or more embodiments, within 25% or less in one or more embodiments, and within 10% or less of each other in one or more embodiments. For example, the RI of the bond and the RI of window element 222 or lens 314 may be within ±0.05 of each other.

Window element 222 with lens 314 is then bonded to LED die 202 using a bonding layer 330 between the window element and the LED die. Bonding layer 330 may form a rigid bond between window element 222 and LED die 202.

Bonding layer 330 may be formed from any of the material listed above for lens 214, bonding layer 219, window element 222, bonding layer 1402, and bonding layer 1410.

Bonding layer 330 may also comprise III-V semiconductors including but not limited to gallium arsenide, gallium nitride, gallium phosphide, and indium gallium phosphide; II-VI semiconductors including but not limited to cadmium selenide, cadmium sulfide, cadmium telluride, zinc sulfide, zinc selenide, and zinc telluride; group IV semiconductors and compounds including but not limited to germanium, silicon, and silicon carbide; organic semiconductors, oxides, metal oxides, and rare earth oxides including but not limited to an oxide of aluminum, antimony, arsenic, bismuth, boron, cadmium, cerium, chromium, cobalt, copper, gallium, germanium, indium, indium tin, lead, lithium, molybdenum, neodymium, nickel, niobium, phosphorous, potassium, silicon, sodium, tellurium, thallium, titanium, tungsten, zinc, or zirconium; oxyhalides such as bismuth oxychloride; fluorides, chlorides, and bromides, including but not limited to fluorides, chlorides, and bromides of calcium, lead, magnesium, potassium, sodium, and zinc; metals including but not limited to indium, magnesium, tin, and zinc; yttrium aluminum garnet (YAG), phosphide compounds, arsenide compounds, antimonide compounds, nitride compounds, high index organic compounds; and mixtures or alloys thereof.

Bonding layer 330 may include luminescent material that converts light of wavelengths emitted by the active region of LED die 202 to other wavelengths. The luminescent material includes conventional phosphor particles, organic semiconductors, II-VI or III-V semiconductors, II-VI or III-V semiconductor quantum dots or nanocrystals, dyes, polymers, and materials such as GaN that luminesce. If bonding layer 330 includes conventional phosphor particles, then the bonding layer should be thick enough to accommodate particles typically having a size of about 5 microns to about 50 microns.

Bonding layer 330 may be substantially free of traditional organic-based adhesives such as epoxies, since such adhesives tend to have a low index of refraction.

Bonding layer 330 may also be formed from a low RI bonding material, i.e., a bonding material having a RI less than about 1.5 at the emission wavelengths of LED die 202. Magnesium fluoride, for example, is one such bonding material. Low index optical glasses, epoxies, and silicones may also be suitable low index bonding materials.

Bonding layer 330 may also be formed from a glass bonding material such as Schott glass LaSFN35, LaF10, NZK7, NLAF21, LaSFN18, SF59, or LaSF3, or Ohara glass SLAH51 or SLAM60, or mixtures thereof. Bonding layer 330 may also be formed from a high index glass, such as (Ge, As, Sb, Ga)(S, Se, Te, F, Cl, I, Br) chalcogenide or chalcogen-halogenide glasses, for example. If desired, lower index materials, such as glass and polymers may be used. Both high and low index resins, such as silicone or siloxane, are available from manufactures such as Shin-Etsu Chemical Co., Ltd., Tokyo, Japan. The side chains of the siloxane backbone may be modified to change the refractive index of the silicone.

Window element 222 can be thermally bonded to LED die 202 after the LED die is mounted on submount 210. For example, to bond window element 222 to LED die 202, the temperature of bonding layer 330 is raised to a temperature between about room temperature and the melting temperature of the contact elements 212, e.g., between approximately 150° C. to 450° C., and more particularly between about 200° C. and 400° C. Window element 222 and LED die 202 are pressed together at the bonding temperature for a period of time of about one second to about 6 hours, for example for about 30 seconds to about 30 minutes, at a pressure of about 1 pound per square inch (psi) to about 6000 psi. By way of example, a pressure of about 700 psi to about 3000 psi may be applied for between about 3 to 15 minutes. Pressure may be applied during cooling. If desired, other bonding processes may be used.

It should be noted that due to the thermal bonding process, a mismatch between the CTE of window element 222 and LED die 202 can cause the window element to delaminate or detach from the LED die upon heating or cooling. Accordingly, window element 222, and LED 202 should have approximately matching CTEs.

A protective side coating 332 may be applied to the edge of window element 222, bonding layer 330, and LED die 202 to reduce edge emission. Side coating 332 may be a silicone with scattering particles such as aluminum nitride, aluminum oxynitride (AlON), barium sulfate, barium titanate, calcium titanate, cubic zirconia, diamond, gadolinium gallium garnet (GGG), lead lanthanum zirconate titanate (PLZT), lead zirconate titanate (PZT), sapphire, silicon aluminum oxynitride (SiAlON), silicon carbide, silicon oxynitride (SiON), strontium titanate, titanium oxide, yttrium aluminum garnet (YAG), zinc selenide, zinc sulfide, or zinc telluride, a thermal grease, or a metal film such as aluminum, chromium, gold, nickel, palladium, platinum, silver, vanadium, or a combination thereof.

In one or more embodiments of the present disclosure, the optical element may include optional heat sink 224 with optional fins 226. Heat sink 224 may be thermally coupled to window element 222 to extract heat from the window element. Depending on the material of the optical element, it may function as a heat sink.

In one or more embodiments of the present disclosure, the optical element is lens 314 bonded to LED die 202. Bonding layer 319 or 330 may be used to bond lens 314 to LED die 202. In other embodiments, the optical element is the window element 222 bonded to LED die 222. Bonding layer 330 may be used to bond window element 222 to LED die 202. This is further described in the incorporated references before and after.

More information can be found in U.S. Pat. Nos. 7,279,345, 7,064,355, 7,053,419, 7,009,213, 7,462,502, 7,419,839, 6,987,613, 5,502,316, and 5,376,580, which are commonly assigned and incorporated by reference in their entirety.

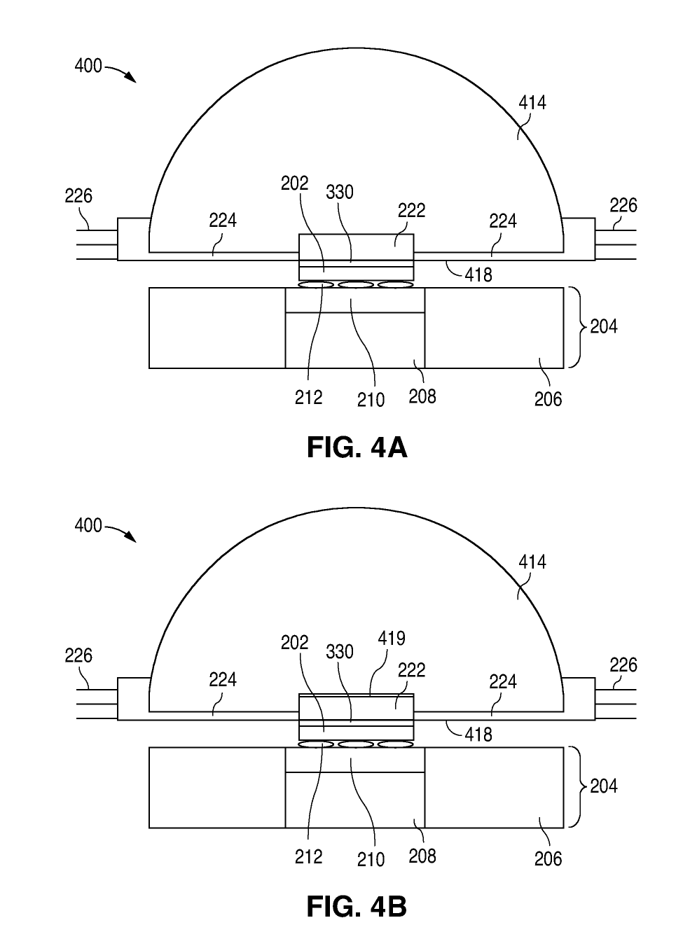

FIG. 4A illustrates a cross-sectional view of a light emitter 400 in one or more embodiments of the present disclosure. Light emitter 400 includes LED die 202 mounted on support 204. An optical element is located over or proximate to LED die 202. In one or more embodiments of the present disclosure, the optical element may include a high index lens 414 that extracts light from LED die 202. Lens 414 may have a solid dome-like shape with a bottom surface 418. Lens 414 may have a RI of 1.5 or greater. Lens 414 may be made from any material described above for lens 214. As similarly described above for lens 214, lens 414 may include a luminescent material that converts light of wavelengths emitted by LED die 202 to other wavelengths.

In one or more embodiments of the present disclosure, the optical element includes a window element 222 that is directly bonded or fused to lens 414. Window element 222 is also recessed into lens 414 so the window element is coplanar with the bottom surface 418 of the lens. Window element 222 may be directly bonded or fused to lens 414, for example, during a molding process. Window element 222 may be recessed into bottom surface 418 before or while lens 414 becomes solid or hard by cooling or curing for example in a mold. Window element 222 may also be recessed into bottom surface 418 by molding lens 418 under or over the window element for example in a mold. A recess may also be premade in lens 414 for window element 222, and the lens may be heated to directly bond or fuse with the window element.

Alternatively, FIG. 4B shows that window element 222 may be bonded to lens 414 with a bonding layer 419 in processes for example described later in reference to FIGS. 16 to 19. Bonding layer 419 may comprise any of the materials listed above for a bonding layer 330, such as lead chloride, lead bromide, potassium fluoride, zinc fluoride, an oxide of aluminum, antimony, arsenic, bismuth, boron, lead, lithium, phosphorus, potassium, silicon, sodium, tellurium, thallium, tungsten, or zinc, or any mixtures thereof. The bond between window element 222 and lens 414 has a RI that substantially matches the RI of either or both of the window element and the lens, a RI that is intermediate to the RIs of the window element and the lens, or a RI that is greater than the RI for the window element or the lens.

Window element 222 with lens 414 is bonded to LED die 202 using bonding layer 330 between the window element and the LED die.

In one or more embodiments of the present disclosure, the optical element may include optional heat sink 224 with optional fins 226. Heat sink 224 may be thermally coupled to window element 222 to extract heat from the window element. Heat sink 224 may be molded to lens 414 at the same time, before, or after window element 222 is bonded. Depending on the material of the optical element, it may function as a heat sink.

FIG. 5 illustrates a molding apparatus 500 that can be used in a molding process for directly bonding or fusing window element 222 to lens 414 in one or more embodiments of the present disclosure. Apparatus 500 may be a thermal compression mold with a lower mold half 502 and an upper mold half 504. Mold halves 502 and 504 define a mold cavity in the desired shape of lens 414. Mold halves 502 and 504 may have guide pins and holes that align the mold halves. Heating/cooling elements 506 (only two are labeled) provide the proper heating and cooling to mold halves 502 and 504 during the molding process. Heating/cooling elements 506 may be integral or separate from mold halves 502 and 504. Alternatively mold halves 502 and 504 may be heated by flowing current directly into the mold where the mold halves are also the heating elements.

Window element 222 is placed on lower mold half 502 and a glass chunk or powder 508 is placed on the window element. Heating/cooling elements 506 heat mold halves 502 and 504 to a temperature sufficient to shape glass chunk or powder 508 without damaging window element 222. Upper mold half 504 is positioned on lower mold half 502 to apply heat and pressure to glass chunk or powder 508, and the softened glass flows and takes the shape of the mold cavity to form lens 414. As lens 414 cools and hardens, it is directly bonded or fused with window element 222. In addition to window element 222, optional heat sink 224 may also be directly bonded or fused with lens 414. Heat sink 224 may be molded with lens 414 before, after, or at the same time as window element 222. Heat sink 224 may also be adhered or glued to lens 414.

Heating/cooling elements 506 may gradually cool mold halves 502 and 504. CTE of may be matched to within 100% or less in one or more embodiments, to within 50% or less in one or more embodiments, and to within 30% or less of each other in one or more embodiments. An ejector pin may be used to push lens 414 with window element 222 from the mold.

Although a molding process has been described for lens 414, mold halves 502 and 504 may take on different shapes to form lenses 214 and 314 described above, and lenses 614, 714, 814, 914, 1014, 1114, 1314, and 2014 described later. Instead of the described molding process, other lens molding process may be used to form any of the lens with window element described above, including but not limited to injection molding and insert molding. For example, insert molding can be used to incorporate any optional heat sink 224 with optional fins 226 into the lens.

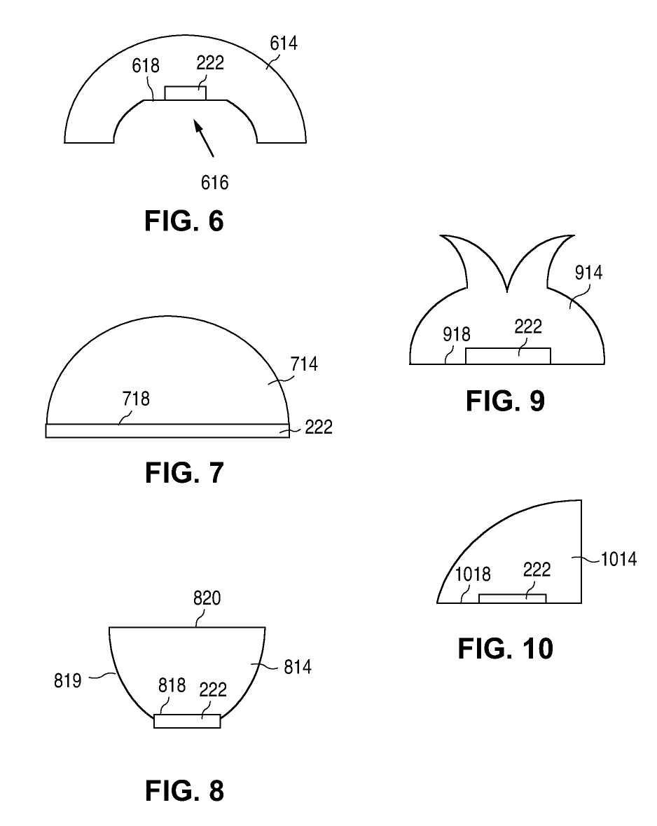

FIGS. 6 to 11, 13, and 20 illustrate various lenses with window elements that may replace lens 214 in module 200, lens 314 in module 300, or lens 414 in module 400. These various lenses with window elements may also replace lens 1414 in light emitters 1400 and 1500 described later.

FIG. 6 illustrates a cross-sectional view of a lens 614 in one or more embodiments of the present disclosure. Lens 614 has a dome-like shape with a cavity 616 having a ceiling 618. Window element 222 is directly bonded or fused to lens 614. Alternatively window element 222 is bonded to lens 614 with a bonding layer in processes for example described later in reference to FIGS. 16 to 19. Lens 614 is similar to lens 214 described above except that window element 222 is recessed into ceiling 618 so the bottom of the window element may be substantially coplanar with the ceiling. Lens 614 may be made from any material described above for lens 214. As similarly described above for lens 214, lens 614 may include a luminescent material and/or window element 222. Light from LED die 202 may be converted to another wavelength by window element 222 and/or lens 614. The combined generated and converted light may produce a desired color.

FIG. 7 illustrates a cross-sectional view of a lens 714 in one or more embodiments of the present disclosure. Lens 714 has a dome-like shape with a bottom surface 718. Window element 222 is directly bonded or fused to bottom surface 718 of lens 714. Window element 222 also spans over the entire bottom surface 718. Alternatively, window element 222 is bonded to lens 714 with a bonding layer in processes for example described later in reference to FIGS. 16 to 19. Lens 714 may be made from any material described above for lens 214. As similarly described above for lens 214, lens 714 may include a luminescent material and/or window element 222. Light from LED die 202 may be converted to another wavelength by window element 222 and/or lens 714. The combined generated and converted light may produce a desired color.

FIG. 8 illustrates a cross-sectional view of a lens 814 in one or more embodiments of the present disclosure. Lens 814 is a compound parabolic concentrator (CPC) lens with a reflective surface 819 that directs light toward an emitting surface 820. Window element 222 is directly bonded or fused to a bottom surface 818 of lens 814. Alternatively window element 222 is bonded to lens 814 with a bonding layer in processes for example described later in reference to FIGS. 16 to 19. Lens 814 may be made from any material described above for lens 214. As similarly described above for lens 214, lens 814 may include a luminescent material and/or window element 222. Light from LED die 202 may be converted to another wavelength by window element 222 and/or lens 814. The combined generated and converted light may produce a desired color.

FIG. 9 illustrates a cross-sectional view of a lens 914 in one or more embodiments of the present disclosure. Lens 914 is a type of side-emitting lens. Window element 222 is directly bonded or fused to lens 914. Alternatively window element 222 is bonded to lens 914 with a bonding layer in processes for example described later in reference to FIGS. 16 to 19. Window element 222 is recessed into lens 914 so the bottom of the window element may be coplanar with a bottom surface 918 of the lens as shown. Alternatively window element 222 is bonded to and protrudes from bottom surface 918. Lens 914 may be made from any material described above for lens 214. As similarly described above for lens 214, lens 914 may include a luminescent material and/or window element 222. Light from LED die 202 may be converted to another wavelength by window element 222 and/or lens 914. The combined generated and converted light may produce a desired color.

FIG. 10 illustrates a cross-sectional view of a lens 1014 in one or more embodiments of the present disclosure. Lens 1014 is another type of side-emitting lens. Window element 222 is directly bonded or fused to lens 1014. Alternatively window element 222 is bonded to lens 1014 with a bonding layer in processes for example described later in reference to FIGS. 16 to 19. Window element 222 is recessed into lens 1014 so the bottom of the window element may be coplanar with a bottom surface 1018 of the lens as shown. Alternatively window element 222 is bonded to and protrudes from bottom surface 1018. Lens 1014 may be made from any material described above for lens 214. As similarly described above for lens 214, lens 1014 may include a luminescent material and/or window element 222. Light from LED die 202 may be converted to another wavelength by window element 222 and/or lens 1014. The combined generated and converted light may produce a desired color.

FIG. 20 illustrates a lens 2014 including grooves in the shape of a Fresnel lens in one or more embodiments of the present disclosure. Lens 2014 may have a Fresnel pattern that is etched, molded, embossed, or stamped. The Fresnel pattern includes a set of grooves, often arranged in concentric pattern. The Fresnel pattern can be formed on the whole surface 2020, or only on the top region, or only on the side region of surface 2020.

Window element 222 is directly bonded or fused to a bottom surface 2018 of lens 2014. Alternatively window element 222 is bonded to lens 2014 with a bonding layer in processes for example described later in reference to FIGS. 16 to 19. Window element 222 is bonded to and protrudes from bottom surface 2018 as shown. Alternatively window element 222 is recessed into lens 2014 so the bottom of the window element may be coplanar with a bottom surface 2018 of the lens. Lens 2014 may be made from any material described above for lens 214. As similarly described above for lens 214, lens 2014 may include a luminescent material and/or window element 222. Light from LED die 202 may be converted to another wavelength by window element 222 and/or lens 2014. The combined generated and converted light may produce a desired color.

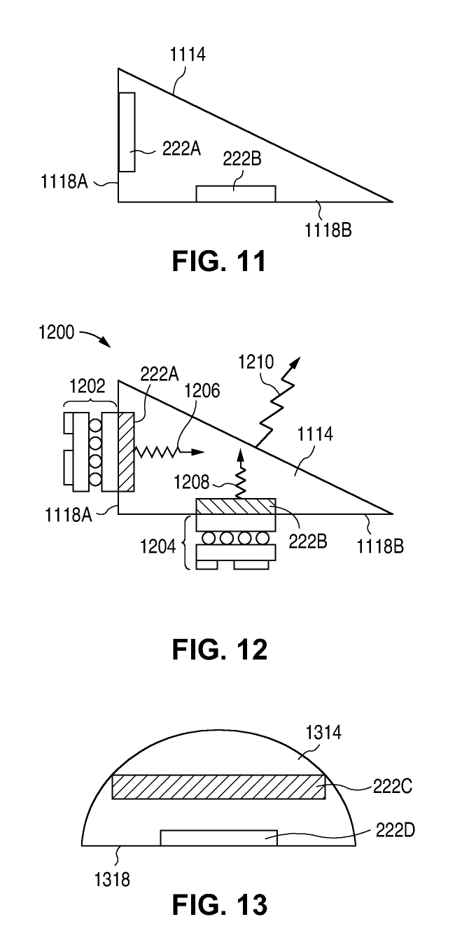

FIG. 11 illustrates a cross-sectional view of a lens 1114 in one or more embodiments of the present disclosure. Lens 1114 is a right angle lens or prism. One window element 222 (labeled 222A) may be directly bonded or fused to one leg of prism 1114, and a second window element 222 (labeled 222B) may be directly bonded or fused to another leg of the prism. Alternatively one or both window elements 222A and 222B may be bonded to lens 1114 with a bonding layer in processes for example described later in reference to FIGS. 16 to 19. Window element 222A is recessed into prism 1114 so the bottom of the window element may be coplanar with a surface 1118A of the lens as shown, and window element 222B is recessed into the prism so the bottom of the window element may be coplanar with a surface 1118B of the lens as shown. Alternatively at least one or both window elements 222A and window element 222B protrude from surfaces 1118A and 1118B. Lens 1114 may be made from any material described above for lens 214. As similarly described above for lens 214, lens 1114 may include a luminescent material and/or window element 222. Light from LED die 202 may be converted to another wavelength by window element 222 and/or lens 1114. The combined generated and converted light may produce a desired color.

FIG. 12 illustrates a light emitter 1200 with prism 1114 in one or more embodiments of the present disclosure. LED die structures 1202 and 1204 are bonded to respective window elements 222A and 222B. Each LED dies structure includes an LED die and a support. Prism 1114 combines lights 1206 and 1208 from respective LED die structures 1202 and 1204 and window elements 222A and 222B to emit a light 1210. Light 1206 and 1208 may be the same or different wavelength.

FIG. 13 illustrates a cross-sectional view of a lens 1314 in one or more embodiments of the present disclosure. Lens 1314 has a dome-like shape with a bottom surface 1318. A first window element 222 (labeled 222C) is encapsulated or embedded within lens 1314, and a second window element 222 (labeled 222D) is directly bonded or fused to the lens. Alternatively window element 222D is bonded to lens 1314 with a bonding layer in processes for example described later in reference to FIGS. 16 to 19. Window element 222D is recessed into lens 1314 so the bottom of the window element may be coplanar with bottom surface 1318 as shown. Alternatively window element 222D protrudes from bottom surface 1318. Window element 222C may be a wavelength converting element (e.g., a ceramic phosphor plate) and window element 222D may be an optically flat plate or another wavelength converting element (e.g., a ceramic phosphor plate). Lens 1314 may be made from any material described above for lens 214. Light from LED die 202 may be converted to another wavelength by window elements 222C, 222D, and/or lens 1314. The combined generated and converted light may produce a desired color.

Additional lenses, such as top-emitter, elongated optical concentrator, top-emitter with reflectors, side-emitter, side-emitter with reflector, asymmetric elongated side-emitter, and top-emitter with light guide, may be adopted with window element 222 as described in the present disclosure. These lenses are described in U.S. Pat. Nos. 7,009,213 and 7,276,737, which are commonly owned and incorporated by reference.

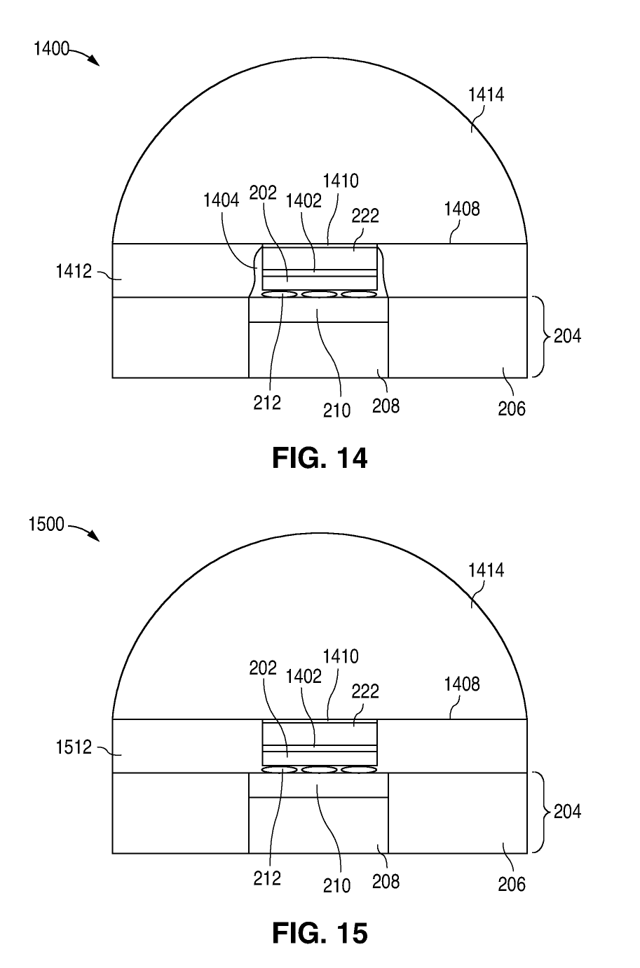

FIG. 14 illustrates a cross-sectional view of a light emitter 1400 in one or more embodiments of the present disclosure. Light emitter 1400 includes LED die 202 mounted on support 206. An optical element is located over or proximate to LED die 202. In one or more embodiments of the present disclosure, the optical element includes a window element 222 is bonded by a bonding layer 1402 to LED die 202. Bonding layer 1402 may be a silicone, an epoxy, a sol-gel material, a glass, or a high index material similar to a later described bonding layer 1410. Bonding layer 1402 may also be a material described earlier for bonding layer 330. An optional side coating 1404 may be applied to the edge of window element 222, bonding layer 1402, and LED die 202 to reduce edge emission. Side coating 1404 may be a silicone, epoxy, or sol-gel derived material filled with reflective or scattering particles such as aluminum nitride, aluminum oxynitride (AlON), barium sulfate, barium titanate, calcium titanate, cubic zirconia, diamond, gadolinium gallium garnet (GGG), hafnium oxide, indium oxide, lead lanthanum zirconate titanate (PLZT), lead zirconate titanate (PZT), sapphire, silicon aluminum oxynitride (SiAlON), silicon carbide, silicon oxynitride (SiON), strontium titanate, tantalum oxide, titanium oxide, yttrium aluminum garnet (YAG), zinc selenide, zinc sulfide, or zinc telluride, thermal greases, or a metal film such as aluminum, chromium, gold, nickel, palladium, platinum, silver, or vanadium, or a combination of any of the above.

In one or more embodiments of the present disclosure, the optical element includes a high index lens 1414 that extracts light from LED die 202. Lens 1414 may have a dome-like shape with a bottom surface 1408. Lens 1414 may have a RI of 1.5 or greater (e.g., 1.7 or greater) at the light emitting device's emission wavelengths. Lens 1414 may be made from glass, sapphire, diamond, alumina, or any material described above for lens 214. Lens 1414 is bonded by a high index bond layer 1410 to window element 222. Although bottom surface 1408 is shown as being a flat surface, a recess may be provided in the bottom surface that at least partly receive window element 222. This may help to position window element 222 and lens 1414 in the bonding process.

High index bond layer 1410 has a RI that substantially matches the RI of either or both of window element 222 and lens 1414, a RI that is intermediate to the RIs of the window element and the lens, or a RI that is greater than the window element or the lens. The RIs substantially match when they are within 100% or less in one or more embodiments, within 50% or less in one or more embodiments, within 25% or less in one or more embodiments, and within 10% or less of each other in one or more embodiments. For example, the RI of the bond and the RI of window element 222 or lens 1414 may be within ±0.05.

High index bond layer 1410 may be a silicone resin or silicate binder filled with properly dispersed high index nano-particles with particle sizes <100 nm (e.g., <50 nm). To facilitate dispersability of the nano-particles, a small amount of suitable dispersing agent may be used as a compatibilizer between the nano-particles and the dispersion medium. The volume ratio of dispersed nano-particles and binder matrix may be tuned to control the refractive index of bond layer 1410, i.e., a higher volume concentration of the high refractive index nano-particles increases the effective refractive index of the bond layer. The silicone resin may be a methyl polysiloxane, a phenyl polysiloxane, a methyl phenyl polysiloxane, or mixtures thereof. The silicate binder may be of a type forming a silicate, a methylsilicate, or phenylsilicate upon curing, or a mixture thereof, and may be derived from precursor monomers and/or oligomers in a sol-gel process. The high index nano-particles may be a high refractive index nano-particle, such as aluminum oxide, aluminum nitride, aluminum oxynitride (AlON), barium sulfate, barium titanate, calcium titanate, cubic zirconia, diamond, gadolinium gallium garnet (GGG), gadolinium oxide, hafnium oxide, indium oxide, lead lanthanum zirconate titanate (PLZT), lead zirconate titanate (PZT), strontium titanate, silicon aluminum oxynitride (SiAlON), silicon carbide, silicon oxynitride (SiON), tantalum pentoxide, titanium oxide, yttrium aluminum garnet (YAG), yttrium aluminum oxide, yttrium oxide, zirconium oxide, yttria stabilized zirconium oxide, or a mixture thereof.

A thin layer of the high index bond material may be applied to window element 222, lens 1414, or both. The thickness of the high index bond material may be several microns (e.g., <10 microns). The high index bond material may be applied in various ways, such as by dispensing, printing, spray coating, spin coating, or blade coating. The high index bond material is typically deposited in fluid form, and may remain fluid up to the moment of connection of window element 222 and lens 1414, or may be partially solidified or gelled at the moment of connection, or may be a solid that tackifies upon heating to enable easy connection. Usually the high index bond material reacts to form a solidified bond that may range from a gelled state to a hard resin.

For example, the high index bond material precursor may consist of a methyl substituted silicone resin with dispersed nano-TiO₂ particles that is spin or blade coated from a solution onto window element 222. The spin coating or blade coating may be applied on a large scale, e.g., a substrate of window elements 222 that is subsequently diced into smaller parts and used as individual window elements. The silicone resin is of a type that is solid at room temperature but when heated at a temperature of 70 to 150° C. will tackify to enable a bonding contact between lens 1414 that is brought into contact with window element 222. The high index bond material is then cured at a higher temperature (e.g., 1 hour at 200° C.) to form high index bond layer 1410 between window element 222 and lens 1414. Alternatively the high index bond material is dispensed in liquid form on window element 222 or lens 1414 and both components are connected. The bond is then cured to a high index solid at elevated temperature, e.g., 150° C. for 1 hour.

A solvent may be present in the high index bonding precursor fluid. The solvent may be removed prior to bonding or during the bonding process or may remain (partially) present to facilitate optical contact and may be removed further from the bond through evaporation. The remaining gap between lens 1414 and support 204 may be filled with an underfill material 1412 such as silicone. The underfill material may contain a particulate filler to enhance thermal conductivity and/or reflectivity.

FIG. 15 illustrates a cross-sectional view of a light emitter 1500 in one or more embodiments of the present disclosure. Light emitter 1500 is similar to light emitter 1400 except that side coating 1404 is not present because underfill material 1412 is replaced with a reflective underfill material 1512. The underfill material may also fill a gap between LED die 202 and support 204. The reflective underfill material may be a silicone filled with a reflective thermal grease, a metal film, reflective or scattering particles, or a combination thereof may also be used. The reflective or scattering particles may be aluminum nitride, aluminum oxynitride (AlON), barium sulfate, barium titanate, calcium titanate, cubic zirconia, diamond, hafnium oxide, indium oxide, gadolinium gallium garnet (GGG), lead lanthanum zirconate titanate (PLZT), lead zirconate titanate (PZT), sapphire, silicon aluminum oxynitride (SiAlON), silicon carbide, silicon oxynitride (SiON), strontium titanate, tantalum oxide, titanium oxide, yttrium aluminum garnet (YAG), zinc selenide, zinc sulfide, zinc telluride, or a combination thereof.

Instead of filling the gap between lens 1414 and support 204 after the lens bonding, underfill material 1412 or 1512 may be deposited on support 204 until it is level or planarized with window element 222 before the lens bonding. If so, material of high index bond layer 1410 may be applied over the entire top surface of window element 222 and underfill material 1412 or 1512.

Instead of being a silicone or a sol-gel material, high index bond layer 1410 may also be made of the same material as bonding layer 330 described above. In one or more embodiments of the present disclosure, bonding layer 1410 is made of an optical glass having a lower melting temperature than window element 222 and lens 1414. The glass may be formed on top of window element 222, on the bottom of lens 1414, or both. The glass is heated until it softens, and pressure may be applied to during the bonding process and cool down. The glass forms a high index bond layer 1410 between window element 222 and lens 1414.

FIG. 16 illustrates an apparatus for a process to form a glass high index bonding layer on window element 222 in one or more embodiments of the present disclosure. Window element 222 is held by supports in a lower mold half 1602 and an upper mold half 1604 is positioned on the lower mold. Mold halves 1602 and 1604 may have guide pins and holes for proper alignment of the mold halves. Heating/cooling elements 1606 (only two are labeled) provide the proper heating and cooling to mold halves 1602 and 1604 during the molding process. Heating/cooling elements 1606 may be integral or separate from mold halves 1602 and 1604.

Glass is introduced through a mold inlet 1608 over the top and the bottom surfaces of window element 222. As the glass hardens, it bonds with window element 222 to form bonding layers 1402 and 1410 as shown in FIG. 17. Window element 222 is later heated and bonded to the bottom of lens 1414 and the top of LED die 202. Although bonding layers 1402 and 1410 are formed on both sides of window element 222, the above process may be modified to form one bonding layer on one side of the window element.

FIG. 18 illustrates an apparatus for a process to form a glass high index bond material on the bottom of lens 1414 in one or more embodiments of the present disclosure. Lens 1414 is first molded and placed in a lower mold half 1802, and an upper mold 1804 is positioned on the lower mold. Mold halves 1802 and 1804 may have guide pins and holes for proper alignment of the mold halves. Heating/cooling elements 1808 (only two are labeled) provide the proper heating and cooling to mold halves 1802 and 1804 during the molding process. Heating/cooling elements 1808 may be integral or separate from mold halves 1802 and 1804. Alternatively, an apparatus similar to that shown in FIG. 5 with an appropriate shape may be used with bonding glass chunks or powder to form a bonding glass layer on a lens or window element.

Glass is introduced through a mold inlet 1806 over the bottom surface of lens 1414. As the glass hardens, it bonds with lens 1414 to form a bonding layer 1410 as shown in FIG. 19. Lens 1414 with bonding layer 1410 is later heated and bonded to window element 222 or LED die 202.

Various other adaptations and combinations of features of the embodiments disclosed are within the scope of the invention. Numerous embodiments are encompassed by the following claims.

1. A light emitter, comprising:
a light-emitting device (LED) die;
a lens;
a window element; and
a bond at an interface disposed between the lens and the window element, wherein the window element is bonded to the lens.

2. The light emitter of claim 1, wherein:
the lens has a first refractive index (RI) of 1.5 or greater;
the window element has a second RI of 1.4 or greater; and
the bond comprises a third RI that substantially matches the first or the second RI, is intermediate of the first and the second RIs, or is greater than the first or the second RI.

3. The light emitter of claim 1, further comprising a bond layer at an interface disposed between the window element and the LED die, wherein the window element is bonded to the LED die.

4. The light emitter of claim 3, wherein:
the LED die has a first refractive index (RI);
the window element has a second RI of 1.4 or greater; and
the bond layer comprises a third RI that substantially matches the first or the second RI, is intermediate of the first and the second RIs, or is greater than the first or the second RI.

5. The light emitter of claim 1, wherein the window element is integral to the lens.

6. The light emitter of claim 1, wherein the window element is an optically flat plate or a wavelength converting element.

7. The light emitter of claim 1, wherein the lens defines a cavity with a ceiling and the window element is bonded to the ceiling.

8. The light emitter of claim 7, wherein the light emitter further comprises:
a first silicone between the window element and the LED die in the cavity; and
a second silicone at least partially surrounding the LED die, the second silicone comprising reflective or scattering particles.

9. The light emitter of claim 1, wherein one of bottom and top surfaces of the window element is substantially coplanar with a surface of the lens.

10. The light emitter of claim 1, further comprising a heat sink thermally coupled to one or more of the window element, the lens, the LED die, a support for the LED die, a submount for the LED die, and a housing for the LED die.

11. The light emitter of claim 1, wherein the bond comprises a bond layer, the bond layer comprises a silicone type or a silicate type binder filled with high index nano-particles, the silicone type binder is a methyl polysiloxane, a methyl phenyl polysiloxane, or a phenyl polysiloxaneor mixtures thereof, the silicate type binder is a type that forms a silicate, a methylsilicate, a phenylsilicate, or a mixture thereof upon curing.

12. The light emitter of claim 11, wherein the high index nano-particles is one of aluminum nitride, aluminum oxide, aluminum oxynitride, barium sulfate, barium titanate, calcium titanate, cubic zirconia, diamond, gadolinium gallium garnet, gadolinium oxide, hafnium oxide, indium oxide, lead lanthanum zirconate titanate, lead zirconate titanate, strontium titanate, silicon aluminum oxynitride, silicon carbide, silicon oxynitride, tantalum pentoxide, titanium oxide, yttrium aluminum garnet, yttrium aluminum oxide, yttrium oxide, zirconium oxide, and yttria stabilized zirconium oxide.

13. The light emitter of claim 1, wherein the bond comprises a bond layer, the bond layer comprising one or more of a chalcogenide glass, a chalcohalide glass, an oxide, a metal oxide, a rare earth metal oxide, a fluoride, a chloride, a bromide, a metal, a yttrium aluminum garnet, a phosphide compound, an arsenide compound, an antimonide compound, and an organic compound.

14. The light emitter of claim 1, wherein the bond comprises a bond layer, the bond layer comprising one or more of aluminum oxide, antimony oxide, arsenic oxide, bismuth oxide, boron oxide, lead chloride, lead bromide, lead oxide, lithium oxide, phosphorus oxide, potassium fluoride, potassium oxide, silicon oxide, sodium oxide, tellurium oxide, thallium oxide, tungsten oxide, zinc fluoride, and a zinc oxide.

15. The light emitter of claim 3, wherein the bond layer comprises a silicone type or a silicate type binder filled with high index nano-particles, the silicone type binder is a methyl polysiloxane, a methyl phenyl polysiloxane, or a phenyl polysiloxaneor mixtures thereof, the silicate type binder is a type that forms a silicate, a methylsilicate, a phenylsilicate, or a mixture thereof upon curing.

16. The light emitter of claim 15, wherein the high index nano-particles is one of aluminum nitride, aluminum oxide, aluminum oxynitride, barium sulfate, barium titanate, calcium titanate, cubic zirconia, diamond, gadolinium gallium garnet, gadolinium oxide, hafnium oxide, indium oxide, lead lanthanum zirconate titanate, lead zirconate titanate, strontium titanate, silicon aluminum oxynitride, silicon carbide, silicon oxynitride, tantalum pentoxide, titanium oxide, yttrium aluminum garnet, yttrium aluminum oxide, yttrium oxide, zirconium oxide, and yttria stabilized zirconium oxide.

17. The light emitter of claim 3, wherein the bond layer comprises one or more of a chalcogenide glass, a chalcohalide glass, an oxide, a metal oxide, a rare earth metal oxide, a fluoride, a chloride, a bromide, a metal, a yttrium aluminum garnet, a phosphide compound, an arsenide compound, an antimonide compound, and an organic compound.

18. The light emitter of claim 3, wherein the bond layer comprising one or more of aluminum oxide, antimony oxide, arsenic oxide, bismuth oxide, boron oxide, lead chloride, lead bromide, lead oxide, lithium oxide, phosphorus oxide, potassium fluoride, potassium oxide, silicon oxide, sodium oxide, tellurium oxide, thallium oxide, tungsten oxide, zinc fluoride, and a zinc oxide.

19. A method for manufacturing a light emitter, comprising:
forming a bond at an interface disposed between a window element and a lens; and
locating the window element and the lens proximate to a light-emitting device (LED) die.

20. The method of claim 19, further comprising applying a bond layer at an interface disposed between the window element and the LED die, wherein the window element is bonded to a surface of the LED die.

21. The method of claim 19, wherein:
said forming a bond comprises placing the window element on the surface of the lens while the lens is hardening; and
the window element is an optically flat plate or a wavelength converting element.

22. The method of claim 19, wherein:
said forming a bond comprises molding the lens on the window element; and
the window element is an optically flat plate or a wavelength converting element.

23-37. (canceled)
